(19) United States
(12) Patent Application Publication
(10) Pub. No.: US 2017/0336019 A1
(43) Pub. Date: Nov. 23, 2017

(54) GIMBAL AND METHOD FOR WINDING FLEXIBLE CABLE ON GIMBAL

(71) Applicant: ZEROTECH (SHENZHEN) INTELLIGENCE ROBOT CO., LTD., Shenzhen (CN)

(72) Inventors: Gengpeng LIU, Beijing (CN); Hongtao SUN, Beijing (CN)

(73) Assignee: ZEROTECH (SHENZHEN) INTELLIGENCE ROBOT CO., LTD., Shenzhen (CN)

(21) Appl. No.: 15/281,899

(22) Filed: Sep. 30, 2016

(30) Foreign Application Priority Data
May 17, 2016 (CN) 201610327302.9

(51) Int. Cl. F16M 11/18; F16M 11/12; F16M 13/02; H05K 3/36; H05K 1/02; H02K 16/00; B65H 75/44; H02K 7/00; H02K 3/50; G03B 17/56

(52) U.S. Cl. CPC F16M 11/18; H02K 7/003; F16M 11/12; F16M 13/022; H02K 3/50; H05K 3/36; H05K 1/028; H02K 16/00; B65H 75/4486; G03B 17/561; B65H 2701/34; H05K 2201/051; H05K 2201/09

(57) ABSTRACT

A gimbal and a method for winding a flexible cable on a gimbal are provided. The gimbal includes a first motor and a second motor connected with each other. The flexible cable includes a connection unit and a connection end connected with each other, and the connection end is extended from the connection unit. The gimbal winding method includes winding the connection unit on the first motor while allowing the connection end to be electrically connected with the second motor.

### TECHNICAL FIELD

Embodiments of the present disclosure relate to a gimbal and a method for winding a flexible cable on a gimbal.

### BACKGROUND

Flexible printed circuits (FPCs) are advantageous due to characteristics such as high wiring density, light weight, and thin thickness, and have been mainly applied in mobile phones, laptop computers, palm computers, digital cameras, liquid crystal display modules, gimbals, and many other products. Flexible Flat Cables (FFCs) belong to a new type of cable for transferring data and electrical power for example, and have the advantages such as flexibility, thin thickness, easy connection, and so on.

In an existing gimbal, flexible printed circuits are usually employed to electrically connect various components, such as motor, inertial measurement unit (IMU), camera (imaging module), and PCB board. However, the current winding method for an FPC cable in the gimbal may cause a situation that the FPC cable is wound in a disorder manner and the cables are not wound compactly, which is not favorable to minimization of the gimbal.

### SUMMARY

An embodiment of the present disclosure provides a method for winding an flexible cable on the gimbal, the gimbal includes a first motor and a second motor connected with each other, the flexible cable includes a connection unit and a connection end connected with each other, the connection end is extended from the connection unit, and the method includes winding the connection unit on the first motor while allowing the connection end to be electrically connected with the second motor.

Another embodiment of the present disclosure provides a gimbal including a first motor and a second motor connected with each other and an flexible cable, the flexible cable includes a connection unit and a connection end connected with each other, the connection end is extended from the connection unit, the connection unit is wound on the first motor, and the connection end is electrically connected with the second motor.

Still another embodiment of the present disclosure provides a method for winding an flexible cable on a gimbal, the gimbal includes a first motor, a second motor, a third motor and a camera module connected with each other, an end of the flexible cable away from the camera module includes a first connection branch and a second connection branch connected with each other, the first connection branch includes a first connection unit and a first connection end connected with each other, the second connection branch includes a second connection unit, and a second connection end and a third connection end are extended from the second connected unit. The method includes: winding the first connection unit on the first motor while allowing the first connection end to be electrically connected with the second motor; winding the second connection unit on the third motor so that the second connection end is electrically connected with the first motor and the third connection end is electrically connected with the third motor.

### DESCRIPTION OF ACCOMPANYING DRAWINGS

In order to more clearly describe the technical solution of the embodiments of the present disclosure, the accompanying drawings for the embodiments will be briefly described, it is obvious that the accompanying drawings in the following description only illustrate some embodiments of the present disclosure, but not are intended to limit the present disclosure. To the person ordinarily skilled in the art, other relevant drawings can also be conceived according to these drawings without any creative labor.

FIG. 1 is a schematic winding diagram illustrating a method for winding a flexible cable on a gimbal provided by an embodiments of the present disclosure;

FIG. 2 is a schematic diagram illustrating the overall structure of a gimbal with no wire being wound, to which the method provided by the embodiment of the present disclosure can be applied;

FIG. 3 is an exploded schematic structure diagram of a gimbal with no wire being wound, to which the method provided by the embodiment of the present disclosure can be applied;

FIG. 4 is a schematic expanded structure diagram illustrating an FPC cable in the method provided by the embodiment of the present disclosure;

FIG. 5 is a schematic structure diagram illustrating the FPC cable in the wound state by the method provided by the embodiment of the present disclosure from a front angle of view;

FIG. 6 is a schematic structure diagram illustrating the FPC cable in the wound state by the method provided by the embodiment of the present disclosure from a rear side angle of view;

FIG. 7 is a schematic structure diagram illustrating the FPC cable in the wound state by the method provided by the embodiment of the present disclosure from a rear angle of view;

FIG. 8 is a schematic structure diagram illustrating the gimbal obtained after the gimbal is wound by the method provided by the embodiment of the present disclosure; and

FIG. 9 is a schematic structure diagram illustrating a force offsetting structure obtained after winding by the method provided by the embodiment of the present disclosure.

### DETAILED DESCRIPTION

In order to make objects, technical details and advantages of the embodiments of the disclosure apparent, the technical solutions of the embodiments will be described in a clearly and fully understandable way in connection with the drawings related to the embodiments of the disclosure. Apparently, the described embodiments are just a part but not all of the embodiments of the disclosure. Generally, the components of the embodiments of the present disclosure as shown and described in the attached drawings here can be arranged and designed in various configurations.

Thus, the detail description with respect to the embodiments of the present disclosure illustrated in the accompanying drawings is not intended to limit the scope of the claimed disclosure, but only indicate the optional embodiments of the present disclosure. Based on the described embodiments herein, those skilled in the art can obtain other embodiment(s), without any inventive work, which should be within the scope of the disclosure.

It should be noted that similar symbols and letters are used to indicate the similar items throughout the drawings, and therefore, once an item has been defined in one drawing, then the item is not needed to be further defined and explained in the subsequent drawings.

It should be appreciated that the location or position relationship indicated by the terms “upper”, “lower”, “inner”, “outer”, or the like, as used herein, is based on the location or position relationship as illustrated in the accompanying drawings, or the location or position relationship normally placed when the embodiment product of the disclosure is in operation, or the location or position relationship conventionally understood by the person skilled in the art, servers merely for the purpose of facilitating to describe the present disclosure and simplify the description, but does not indicate or imply the referred device or member must have the specific location or position, is constructed and operated in a specific location, and therefore, should not be construed as limitation upon the present disclosure.

In addition, the terms “first”, “second”, “third”, and so on, as used herein, merely serve for the purpose of distinguishing, but should not be understood as indicating or implying relative significance.

In the description of the present disclosure, it is also to be noted that unless otherwise prescribed or defined explicitly, the terms “provide”, “connect”, “couple” or the like should be understood in their broad sense, for example, it can be a fixedly connection, and also can be a detachably connection or integrally connection, can be a mechanical connection or an electric connection, can be a direct connection or an indirect connection via a intervene medium, and also can be communication between inner portions of two members. The specific meaning of the above terms in the present disclosure can be understood by the person skilled in the art according to the specific situation.

In this disclosure, FPC (flexible printed circuit) cable and FFC (flexible flat cable) are specific examples of flexible cable. Hereinafter, FPC cable is taken as an example for illustration, but obviously the disclosure is not limited to FPC cable and is applicable to FFC as well. Moreover, when an FFC is put in usage, this FFC can be connected to a corresponding PCB, FPC or the like by a connector to establish electric connection.

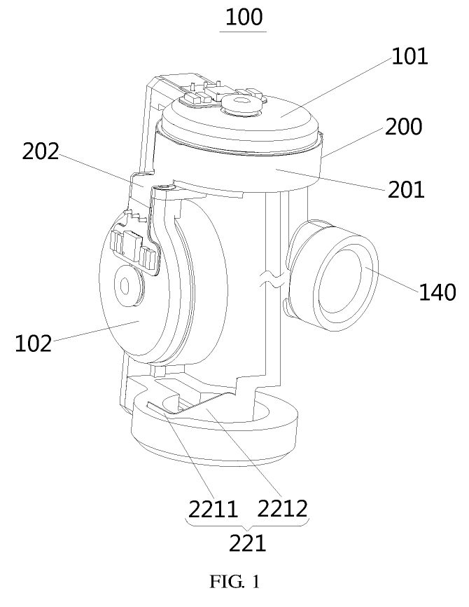

With reference to FIG. 1, an embodiment of the present disclosure provides a method, for winding an FPC cable 200 on a gimbal 100. In the following, the winding process and the basic principle of the method will be described in detail.

In this embodiment, the gimbal 100 includes a camera module 140, a first motor 101, a second motor 102, and an FPC cable 200, and a rotor housing of the first motor 101 is connected with a stator of the second motor 102. It should be appreciated that FIG. 1 only illustrates the basic principle of the method, motors applicable to the gimbal 100 are not limited to the two motors, i.e., the first motor 101 and the second motor 102, and the first motor 101 and the second motor 102 are not specifically designated, rather, it means that one of the two motors can be the first motor 101, and another one adjacent thereto is the second motor 102.

When the gimbal according to the present embodiment is wound, one end of the FPC cable 200 is connected with the camera module 140. The FPC cable 200 further includes a first connection unit 201 and a connection end 202 connected with each other, and the connection end 202 is extended from the connection unit 201. In winding, the connection unit 201 is wound on a rotor housing of the first motor 101, and the connection end 202 is electrically connected with the stator of the second motor 102.

For example, the FPC cable 200 further includes a rotation structure 221 connected with the connection unit 201, and the rotation structure 221 is rotatable following the first motor 101. The rotation structure 221 includes a fixing end 2211 and a rotation part 2212 connected with each other, the rotation part 2212 is connected with the connection unit 201, and the rotation part 2212 is rotatable following the first motor 101. It should be appreciated that the rotation structure 221 is a structure that is rotated following the motor, and one or more rotation structure can be provided correspondingly according to the number of the motors. The rotation structure 221 allows the FPC cable 200 to be rotated following the first motor 101 as the first motor 101 rotates, which can avoid the phenomenon that the FPC cable 200 is wound in a disorder manner when rotated following the motor.

In practice of this method to wind the FPC cable 200 on the gimbal 100, winding on the first motor 101 is achieved by the connection unit 201, and electrical connection with the second motor 102 is achieved by the connection end 202. That is, between the two adjacent motors, the connection unit 201 of the FPC cable 200 is wound on one of the motors, and the connection end 202 extended from the connection unit 201 is electrically connected with the other motor. This winding method enables the routing of the FPC cable 200 to be more appropriate, the phenomenon in which the FPC cable 200 is wound in a disorder manner when rotated following the motor can be prevented, the cable can be arranged more compactly, and the minimization design of the gimbal is facilitated.

Hereinafter, with the example of a three-axis gimbal 100, the method according to the embodiment of the present disclosure will be described in detail.

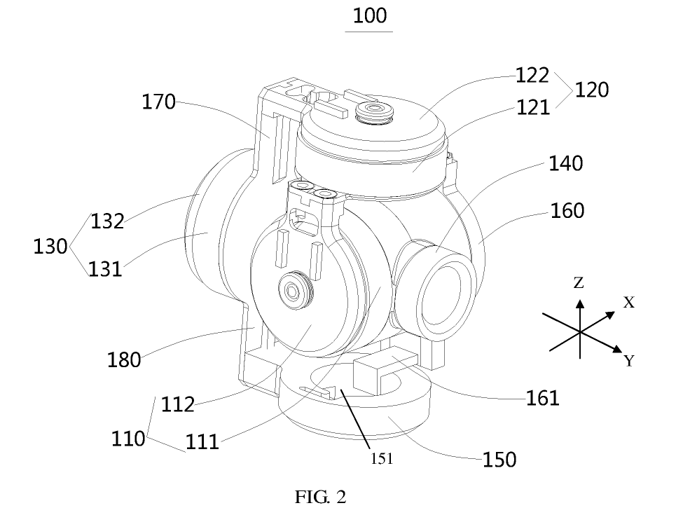

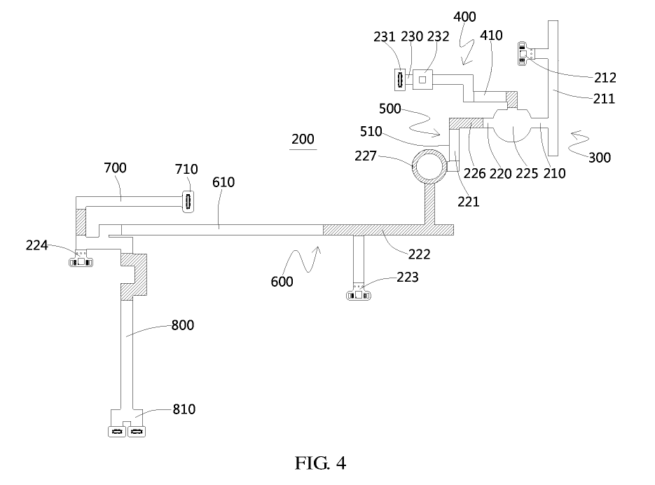

Specifically, with reference to FIG. 2 and FIG. 4, the three-axis gimbal 100 includes a camera module 140, a pitch motor 110, a yaw motor 120, a roll motor 130, a first cable passage structure 150, a second cable passage structure 160, and an FPC cable 200. Here, for the purpose of illustrating, the yaw motor 120 is referred to the first motor 101, the pitch motor 110 is referred to the second motor 103, and the roll motor 130 is referred to a third motor (not indicated in the drawings).

An axis of the pitch motor 110 (X-axis in FIG. 2), an axis of the roll motor 130 (Y-axis in FIG. 2), and an axis of the yaw motor 120 (Z-axis in FIG. 2) are orthogonal to one another, the camera module 140 is connected (e.g., fixed) with the pitch motor 110, the pitch motor 110 is connected (e.g., fixed) with the yaw motor 120, and the yaw motor 120 is connected (e.g., fixed) with the roll motor 130.

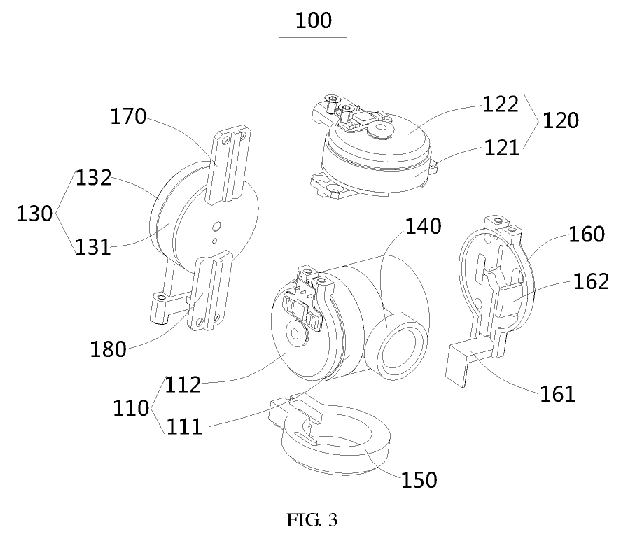

With reference to FIG. 3, the pitch motor 110 includes a pitch rotor housing 111 and a pitch stator 112, and the pitch rotor housing 111 is rotatable with respect to the pitch stator 112. Similarly, the yaw motor 120 includes a yaw rotor housing 121 and a yaw stator 122, and the yaw rotor housing 121 is rotatable with respect to the yaw stator 122. The roll motor 130 includes a roll rotor housing 131 and a roll stator 132, and the roll rotor housing 131 is rotatable with respect to the roll stator 132.

The yaw stator 122 is connected with the roll rotor housing 131 through a first connection arm 170, and the first cable passage structure 150 is connected with the roll rotor housing 131 through a second connection arm 180. The yaw motor 120 is located opposite to the first cable passage structure 150, and they are respectively provided at opposite sides of the roll motor 130. The first connection arm 170 is preferably located in a same line as the second connection arm 180. The first cable passage structure 150 for example is of a circular disk shape, and a receiving cavity is provided therein.

The pitch motor 110 and the camera module 140 are located between the yaw motor 120 and the first cable passage structure 150. The pitch motor 110 for example is connected with a lower side of the yaw rotor housing 121. The pitch rotor housing 111 is connected with an end of the camera module 140. The second cable passage structure 160 is provided at an end of the camera module 140 away from the pitch rotor housing 111. The second cable passage structure 160, for example, is of a circular disk shape, one end of which is connected with a side of the yaw rotor housing 121, and the other end of which is provided with a rotation arm 161. The rotation arm 161 is of an L-shape, one end of which is extended into the receiving cavity 151 of the first cable passage structure 150. A catch (or fixture block) 162 is provided at a side of the second cable passage structure 160 close to the camera module 140. The second cable passage structure 160 covers a side of the housing of the camera module 140, and the catch 162 is located in the housing of the camera module 140.

When the pitch motor 110 operates, the pitch rotor housing 111 is rotated with respect to the pitch stator 112, the pitch rotor housing 111 brings the camera module 140 to rotate around the axis of the pitch motor 110, so that an end of the camera module 140 close to the second cable passage structure 160 is rotated with respect to the second cable passage structure 160.

When the roll motor 130 operates, the roll rotor housing 131 is rotated with respect to the roll stator 132, and the roll rotor housing 131 brings the first connection arm 170 and the second connection arm 180 into same-direction rotating, that is, the first connection arm 170 and the second connection arm 180 are either rotated simultaneously clockwise or rotated simultaneously anticlockwise, thus bring the yaw motor 120 and the second cable passage structure 160 to rotate around the axis of the roll motor 130 in the same direction.

When the yaw motor 120 operates, the yaw rotor housing 121 is rotated with respect to the yaw stator 122, and the yaw rotor housing 121 brings the pitch motor 110 and the second cable passage structure 160 into same-direction rotating around the axis of the yaw motor 120 simultaneously, and the camera module 140 is rotated around the axis of the yaw motor 120 together with the pitch motor 110. In addition, the rotation arm 161 of the second cable passage structure 160 is rotated in the receiving cavity of the first cable passage structure 150.

With reference to FIG. 2 to FIG. 9, a particular winding situation of the method provided by the present embodiment will be described in detail below.

With reference to FIG. 3 to FIG. 5, an end of the FPC cable 200 is connected with the camera module 140. The FPC cable 200 further includes a first connection branch 210 and a second connection branch 220. The first connection branch 210 includes a first connection unit 211 that is configured to surround the yaw rotor housing 121 and a first connection end 212 that is connected with the pitch stator 112; the second connection branch 220 includes a rotation structure 221, a second connection unit 222 that is configured to surround the roll rotor housing 131, a second connection end 223 that is connected with the yaw stator 122, and a third connection end 224 connected with the roll stator 132. The rotation structure 221 is rotatable following the yaw motor 120. The first connection end 212 can act to provide control signals, power, and so on to the pitch motor.

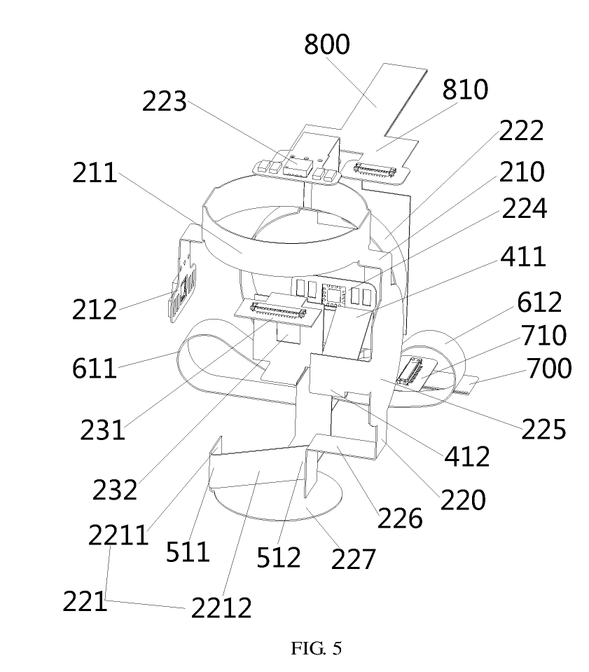

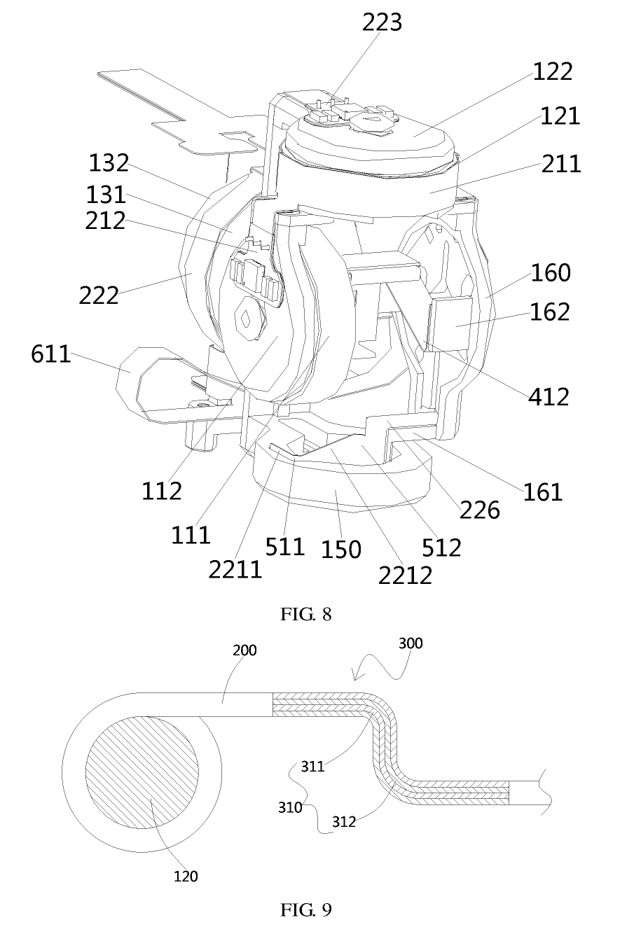

With reference to FIG. 5 and FIG. 8, the rotation structure 221 is formed as a part of the second connection branch 220, and can be rotated upon pushing or pulling. When the yaw motor 120 operates, the rotation structure 221 can follow the rotation of the yaw rotor housing 121 to rotate. In particularly, the rotation structure 221 may include a fixing end 2211 and a rotation part 2212 connected with each other, the fixing end 2211 is connected with the second connection unit 222, and the rotation part 2212 is connected with the first connection branch 210. It may be preferred that the rotation structure 221 is provided in the first cable passage structure 150, and the fixing end 2211 is fixedly connected with the first cable passage structure 150 for example. When the yaw rotor housing 121 is rotated, the fixing end 2211 is stationary and does not follow to rotate, and the rotation part 2212 is rotated around the fixing end 2211, thus other parts of the FPC cable 200 fixed with the fixing end 2211 is prevented from rotation following rotation of the rotation part, and the FPC cable 200 is prevented from being wound in disorder manner at this place.

In addition, the first connection branch 210 and the second connection branch 220 can be respectively fixed to the second cable passage structure 160. For example, the FPC cable 200 further includes a first transition part 225, the first connection branch 210 and the second connection branch 220 are connected with each other through the first transition part 225, and the first transition part 225 is fixed to the second cable passage structure 160.

That is to say, the first transition part 225 is provided at the position where the first connection branch 210 and the second connection branch 220 are branched from the FPC cable 200, and for example the first transition part 225 is fixed to the second cable passage structure 160 by e.g. back adhesive.

Continuously referring to FIG. 5 and FIG. 8, the second connection branch 220 may further include a first connection segment 226. The first connection segment 226 is fixed to the rotation arm 161 of the second cable passage structure 160. One end of the rotation part 2212 of the rotation structure 221 is rotatably connected with the fixing end 2211, and the other end is connected with an end of the first transition part 225 through the first connection segment 226.

In addition, referring to FIG. 4 again, the FPC cable 200 may further include a third connection unit 230 and a fourth connection end 231 extended from the third connection unit 230. The fourth connection end 231 is configured to be connected with the camera module 140. An end of the third connection unit 230 away from the fourth connection end 231 is connected with the first transition part 225 through the first winding structure 400. An end of the third connection unit 230 away from the fourth connection end 231 is wound in the housing of the camera module 140 so that the first winding structure 400 is obtained. A second connection segment 232 is further provided between the third connection unit 230 and the first winding structure 400, and the second connection segment 232 is for example connected with the IMU of the gimbal 100.

The second connection branch 220 further includes a second winding structure 500. The embodiment will be described by taking the example that the second winding structure 500 includes the rotation structure 221. The second winding structure 500 is provided on the first cable passage structure 150, and the second winding structure 500 is connected with the first transition part 225 through the first connection segment 226.

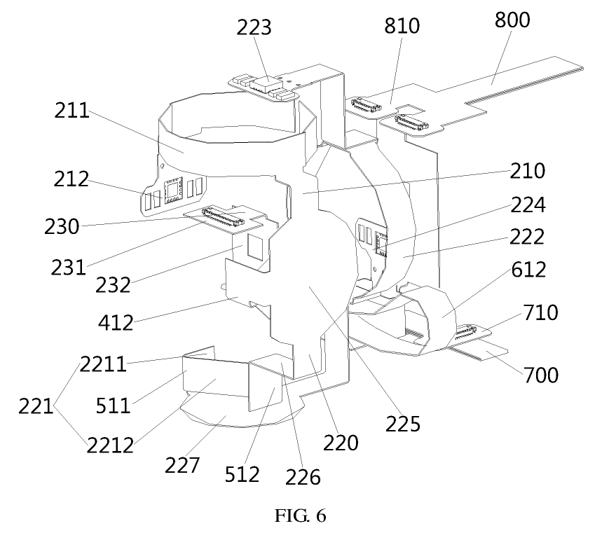

With reference to FIG. 3 and FIG. 6, the second connection branch 220 may further include a second transition part 227, through which the fixing end 2211 of the rotation structure 221 is connected with the second connection unit 222. A portion of the second transition part 227 close to the fixing end 2211 can be fixed to the first cable passage structure 150, and a portion of the second transition part 227 away from the fixing end 2211 is extended up to the second connection arm 180 and can be fixedly connected with the second connection arm 180.

The second connection unit 222 bypasses the roll rotor housing 131 and leads out a second connection end 223 and a third connection end 224 respectively from the opposite sides thereof, the second connection end 223 is configured to be connected with the yaw stator 122 and can provide control signals, power, and so on to the yaw motor 120, and the third connection end 224 is configured to be connected with the roll stator 132 and can provide control signals, power, and so on to the roll motor 130. The second connection branch 220 further includes a third winding structure 600, and the third winding structure 600 is provided between the second connection unit 222 and the third connection end 224.

It should be appreciated that in the present embodiment, the first winding structure 400, the second winding structure 500 and the third winding structure 600 are all formed by intermediate transition structures of the FPC cable 200 in routing. At least one of the first winding structure 400, the second winding structure 500 and the third winding structure 600 may include a rotation structure. The present embodiment is described in the case of the second winding structure 500 including the rotation structure 221. Of course, the first winding structure 400 and/or the third winding structure 600 may also include the rotation structure. It should be noted that, if the first winding structure 400 includes a rotation structure, the rotation structure can be rotated by the rotation of the pitch motor 110, and the fixing end of this rotation structure is connected with the first connection unit 211. On the other hand, if the third winding structure 600 includes a rotation structure, the rotation structure will be rotated by the rotation of the roll motor 130, and the fixing end of this rotation structure is connected with the second connection unit 222.

In addition, in the embodiment of the present disclosure, the FPC cable 200 may be a monolayer FPC, a multilayer FPC or an integrated FPC incorporating multiple layers. The scope of the present disclosure is not limited thereto.

During research and design, the inventors of the present disclosure have discovered that, as the gimbals have been becoming gradually minimized, and the used amount of transmission wires or cables is continuously increased, monolayer FPCs cannot satisfy the current data transmission requirement any more, and multilayer FPCs are widely used. A multilayer FPC can be obtained by bonding a plurality of stacked FPC together with adhesive to form an integrated flexible circuit board for use. However, when the above integrated FPC or a multilayer FPC is used for electrical connection with a movable component of the gimbal 100, as a motor of the gimbal 100 is rotated forward and backward, the FPC which is wound on a rotation shaft of the motor in advance will be wound or unwound. Because the integrated FPC is made by bonding layers of FPC, generally the integrated FPC has relatively larger thickness and bigger hardness than the multilayer FPC, and it is not easily wound or unwound upon the rotation shaft being rotated. For the situation that flat cables in the multilayer FPC are provided in the form of stack, because the inner layer and the outer layer in the FPC cable 200 requires different length during the rotation, which causes stacking, the stacked portion induces unstable resistance to the torque of the motor in rotation, so that the torque requirement of the motor is fluctuant, and accordingly the rotation of the motor become unstable, and the overall driving precision become degraded.

In order to address the above problem, another embodiment of the present disclosure provides an improved design based on the technical solution of the method of the above embodiment.

With reference to FIG. 4 and FIG. 9 (in FIG. 9, an example in which the FPC cable 200 is wound on the yaw motor 120 is shown), for the situation that the FPC cable 200 is a multilayer FPC provided in the form of stack, at least one of the first winding structure 400, the second winding structure 500, and the third winding structure 600 includes at least one force offsetting structure 300.

The force offsetting structure 300 includes a force offsetting unit 310, the force offsetting unit 310 includes a first bending part 311 and a second bending part 312, and the first bending part 311 and the second bending part 312 are bent in opposite directions respectively.

When the FPC cable 200 is wound, various form of force offsetting units 310 can be obtained according to bending shape and running direction of the FPC cable 200. The first bending part 311 and the second bending part 312 can form a spiral reverse shape, an S shape, a Z shape or a butterfly shape.

The FPC cable 200 is wound on the motor to form the force offsetting structure 300, that is, the force offsetting unit 310 can be formed by winding the cable. When the motor is moved, because the first bending part 311 and the second bending part 312 are bent in opposite directions, internal forces produced at an inner side of the bent FPC cable 200 can be cancelled or offset with each other or alleviated, resistance upon the pursuit movement of the FPC cable 200 can be reduced, and the posture of the FPC cable 200 is enabled to be kept in a nature state when the motor is in a movement neutral position. At this time, the connection position of the FPC cable 200 with the motor does not suffer from any force, the motor is not acted by an additional torque, it is possible to enable the stability of the motor to be improved and the movement precision of the motor to be enhanced, and the FPC cable 200 cannot be wound in a disorder manner, and the overall structure can become well arranged.

In an embodiment of the present disclosure, the first winding structure 400, the second winding structure 500 and the third winding structure all include the force offsetting structures. For example again, in the embodiment of the present disclosure, the first winding structure 400, the second winding structure 500 and the third winding structure 600 are configured to include as not only force offsetting structures but also the rotation structures.

With reference to FIG. 4 and FIG. 5, the first winding structure 400 includes a first force offsetting unit 410, the first force offsetting unit 410 includes a fifth bending part 411 and a sixth bending part 412 that are bent in opposite directions. The fifth bending part 411 is connected with the second connection segment 232. For example, the fifth bending part 411 and the sixth bending part 412 together form a Z shape. When the pitch motor 110 operates, the pitch rotor housing 111 is rotated and brings the camera module 140 to rotate around the axis of the pitch motor 110, so that the FPC cable 200 is rotated following the rotation of the pitch rotor housing 111, the first force offsetting unit 410 enables the internal forces generated at the inner side of the wires of the FPC cable 200 when the first winding structure 400 is rotated following the camera module 140 to be cancelled or offset with each other or alleviated, and the resistance upon pursuit movement to be reduced.

The second winding structure 500 includes a second force offsetting unit 510, and the second force offsetting unit 510 includes a third bending part 511 and a fourth bending part 512 that are bent in opposite directions. The second winding structure 500 refers to the same structure as the rotation structure 221, that is, the third bending part 511 is formed by bending at the connection position between the fixing end 2211 and the rotation part 2212, and the fourth bending part 512 is formed by bending an end of the rotation part 2212 away from the fixing end 2211. For example, the third bending part 511 and the fourth bending part 512 together form a Z shape. When the yaw motor 120 operates, the yaw rotor housing 121 is rotated and brings the pitch motor 110 and the camera module 140 to rotate around the axis of the yaw motor 120 together, and the second cable passage structure 160 is rotated around the axis of the yaw motor 120 with respect to the first cable passage structure 150, so that the FPC cable 200 is rotated following the rotation of the yaw rotor housing 121, the second force offsetting unit 510 enables the internal forces generated at the inner side of the wires of the FPC cable 200 when the second winding structure 500 is rotated following the yaw rotor housing 121 to be cancelled or offset with each other or alleviated and the resistance upon pursuit movement to be reduced.

The third winding structure 600 includes a third force offsetting unit 610, and the third force offsetting unit 610 includes a seventh bending part 611 and a eighth bending part 612 bent in opposite directions. The seventh bending part 611 is connected with the second connection unit 222, and the eighth bending part 612 is connected with the third connection end 224. For example, the seventh bending part 611 and the eighth bending part 612 together form a butterfly shape. When the roll motor 130 operates, the yaw motor 120 and the first cable passage structure 150 are brought to rotate around the axis of the roll motor 130, and the pitch motor 110, the second cable passage structure 160 and the camera module 140 are also brought into movement together, so that the FPC cable 200 is rotated following the roll rotor housing 131. The third force offsetting unit 610 enables the internal force generated at the inner side of the wires of the FPC cable 200 when the third winding structure 600 is rotated following the roll rotor housing 131 to be cancelled or offset with each other or alleviated and the resistance upon pursuit movement to be reduced.

In this way, when each of the three motors operates, there is a force offsetting unit 310 for cancelling or offsetting the force generated when the FPC cable 200 follows the rotation, and thus the resistance of the pursuit movement is reduced, and the overall movement precision is improved.

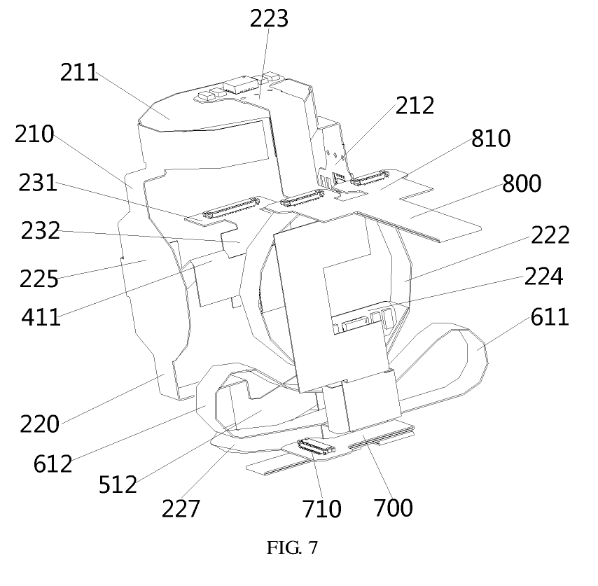

In addition, with reference to FIG. 7, the FPC cable 200 may further include a third connection segment 700 and a fourth connection segment 800, and the third connection segment 700 and the fourth connection segment 800 are connected with the eighth bending part 612, respectively. The third connection segment 700 has a fifth connection end 710 connected with a first PCB board. The fourth connection segment 800 has a sixth connection end 810 connected with a second PCB board. The first PCB board and the second PCB board may include electronic components, such as a controller, a memory, or the like, respectively.

In summary, in the method provided by an embodiment of the present disclosure, the PCB wire 200 can be wound on the gimbal 100, and by the first connection branch 210 and the second connection branch 220, the electrical connection among the three motors can be achieved. By the first connection unit 211 and the second connection unit 212, it can be achieved that, when a motor operates, the FPC cable 200 is rotated following the rotation of the motor. When the motor rotates, by the rotation structure 221, the PCB wire 200 is enabled to rotate following rotation of the motor, and thus the transition part is enabled to follow the rotation and is prevented from being wound in disorder manner. Thus, with the method of the embodiment of the present disclosure, the three motors can be ensured to normally operate, at same time, the routing of the FPC cable 200 can become more appropriate, the FPC cable 200 is prevented from being wound in a disorder manner when the motor(s) rotates, and the routing of the FPC cable 200 becomes more compact to be suitable for the minimized design of the gimbal 100.

The gimbal according to the embodiment of the present embodiment can be fixedly provided on a post of road lamp, a wall of room, a roof of house, or the like, and also can be provided on mobile devices, such as an unmanned aerial vehicle, a boat, a mobilized vehicle, or the like.

What has been described above is only the particular embodiments of the present disclosure, is not intended to limit the present disclosure, and many modifications and variations can be easily conceived by the person skilled in the art from the teaching of the above disclosed embodiments. All the modifications, equivalent substitutions and improvements made within the spirit and principle of the present disclosure should be covered by the protection scope of the present disclosure.

What is claimed is:

1. A method for winding a flexible cable on a gimbal, wherein the gimbal comprises a first motor and a second motor that are connected with each other, the flexible cable comprises a connection unit and a connection end that are connected with each other, the connection end is extended from the connection unit, and the method comprises:
winding the connection unit on the first motor while allowing the connection end to be electrically connected with the second motor.

2. The method according to claim 1, wherein the flexible cable comprises a rotation structure that is connected with the connection unit, and the rotation structure is rotatable following the first motor.

3. The method according to claim 2, wherein the rotation structure comprises a fixing end and a rotation part that are connected with each other, the fixing end is connected with the connection unit, and the rotation part is rotatable following the first motor.

4. The method according to claim 1, wherein the gimbal further comprises a camera module connected with the second motor, and the method further comprises connecting an end of the flexible cable with the camera module.

5. The method according to claim 1, wherein an axis of the first motor and an axis of the second motor are perpendicular to each other.

6. A gimbal comprising:
a first motor and a second motor that are connected with each other, and
a flexible cable,
wherein the flexible cable comprises a connection unit and a connection end that are connected with each other, the connection end is extended from the connection unit, the connection unit is wound on the first motor, and the connection end is electrically connected with the second motor.

7. The gimbal according to claim 6, wherein the flexible cable comprises a rotation structure that is connected with the connection unit, and the rotation structure is rotatable following the first motor.

8. The method according to claim 7, wherein the rotation structure comprises a fixing end and a rotation part that are connected with each other, the fixing end is connected with the connection unit, and the rotation part is rotatable following the first motor.

9. A method for winding a flexible cable on a gimbal, wherein the gimbal comprises a first motor, a second motor, a third motor and a camera module, an end of the flexible cable away from the camera module comprises a first connection branch and a second connection branch that are connected with each other, the first connection branch comprises a first connection unit and a first connection end that are connected with each other, the second connection branch comprises a second connection unit, a second connection end and a third connection end are extended from the second connection unit, and the method comprises:
winding the first connection unit on the first motor while allowing the first connection end to be electrically connected with the second motor;
winding the second connection unit on the third motor; and
electrically connecting the second connection end with the first motor and electrically connecting the third connection end with the third motor.

10. The method according to claim 9, wherein the flexible cable comprises a first transition part, and the first connection branch and the second connection branch are connected through the first transition part.

11. The method according to claim 10, wherein the flexible cable comprises a third connection unit and a fourth connection end, the fourth connection end is connected with the camera module, and an end of the third connection unit is connected with the fourth connection end and the other end of the third connection unit is connected with the first transition part.

12. The method according to claim 11, further comprising:
winding an end of the third connection unit away from the fourth connection end in a housing of the camera module to form a first winding structure, wherein the first winding structure is connected with the first transition part.

13. The method according to claim 12, wherein the second connection branch further comprises a second winding structure, and the second winding structure is connected with the first transition part and the second connection unit, respectively.

14. The method according to claim 13, wherein the second connection branch further comprises a third winding structure, and the third winding structure is provided between the second connection unit and the third connection end.

15. The method according to claim 14, wherein the first winding structure comprises a first rotation structure, the first rotation structure comprises a first fixing end and a first rotation part that are connected with each other, the first fixing end is connected with the first connection unit, and the first rotation part is rotatable following the first motor.

16. The method according to claim 15, wherein the second winding structure comprises a second rotation structure, and the second rotation structure comprises a second fixing end and a second rotation part that are connected with each other, the second fixing end is connected with the second connection unit, and the second rotation part is connected with the first transition part.

17. The method according to claim 16, wherein the gimbal further comprises a first cable passage structure that is connected with a rotor housing of the third motor, the method further comprises:
providing the second winding structure on the first cable passage structure and fixedly connecting the second fixing end with the first cable passage structure.

18. The method according to claim 17, wherein the gimbal further comprises a second cable passage structure, and the method further comprises:
connecting the second cable passage structure with a rotor housing of the first motor and fixing the first transition part to the second cable passage structure.

19. The method according to claim 14, wherein the flexible cable is a multilayer FPC provided in a form of stack,
at least one of the first winding structure, the second winding structure, and the third winding structure comprises a force offsetting structure, the force offsetting structure comprises a force offsetting unit, and the force offsetting unit comprises a first bending part and a second bending part that are bent in opposite directions.

20. The method according to claim 19, wherein the first bending part and the second bending part form a spiral reverse shape, an S shape, a Z shape or a butterfly shape.
